(19) United States
(12) Patent Application Publication
(10) Pub. No.: US 2007/0165367 A1
(43) Pub. Date: Jul. 19, 2007

(54) Protection case for media player

(76) Inventor: Shin-Ming Chung, Taipei County (TW)

Correspondence Address: Chung, Shin-Ming, P.O. Box 44-2049, Taipei, 10668, TW

(21) Appl. No.: 11/412,970

(22) Filed: Apr. 28, 2006

(30) Foreign Application Priority Data
Jan. 18, 2006 (TW) 095201152

(51) Int. Cl. H05K 5/00

(52) U.S. Cl. 361/679

(57) ABSTRACT

A protection case for media player is composed of a first part and a second part. The protection cases includes three holes which are respectively located corresponding to the ON/OFF switch, the control buttons and the ear phone set reception hole of the media player, so that the user operates the media player without removing the media player from the protection case. Two slots are defined through two sides of the second part and two locking devices are located on two ends of the second part so as to connect a back board which can be a belt clip.

### FIELD OF THE INVENTION

The present invention relates to a protection case for a media player and which allows the user to operate the player without removing the player from the protection case.

### BACKGROUND OF THE INVENTION

A conventional protection case for a media player such as an MP3 or the like generally is made by plastic material, metal material, leather or transparent Acrylic. Although all of the conventional protection cases provide a certain level of protection, there are some inherent shortcomings existed. The plastic or leather protection case is too soft to avoid impact from outside to the media player. The metal protection case and the Acrylic protection case are made by hard material which often scrubs the surface of the player. All of the above-mentioned protection cases have to be separated from the media player when using the media player and this might not be satisfactory for users. Besides, the media player is used with an ear phone set and the conventional protection case does not provide any storage space for the ear phone set.

The present invention intends to provide a protection case which includes holes via which the user can operate the buttons of the media player. Multiple types of back boards are available for different uses of the media player.

### SUMMARY OF THE INVENTION

The present invention relates to a protection case for media player which is composed of a first part and a second part. Two slots are defined through two sides of the second part and two locking devices are located on two ends of the second part. A back board is removably connected to the second part so as to be positioned to the user's belt or limb.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is an exploded view to show the protection case for media player of the present invention;

FIG. 2 is a perspective view to show that the media plate received in the protection case of the present invention and a ear phone set is connected to the media player;

FIG. 3 shows a back board and the protection case of the present invention;

FIG. 4 shows that the back board is connected to the protection case of the present invention;

FIG. 5A shows the first embodiment of the back board;

FIG. 5B shows the second embodiment of the back board;

FIG. 5C shows the third embodiment of the back board;

FIG. 6A shows the first embodiment of the back board is connected with a belt;

FIG. 6B shows a rope goes through the two holes in the first embodiment of the back board;

FIG. 7A shows the first embodiment of the back board is connected to a user's belt;

FIG. 7B shows the protection case and the media player are hanged on the user's neck by the rope;

FIG. 8 shows a rope alternatively extends through apertures in the apertures of the second embodiment of the back board;

FIG. 9A shows that the protection case and the media player are tied on a strip of a bag by the second embodiment of the back board;

FIG. 9B shows that the protection case and the media player are tied on a user's arm by the second embodiment of the back board, and

FIG. 10 shows that the wire of the ear phone set is wrapped around the protrusions on the third embodiment of the back board.

### DETAILED DESCRIPTION OF THE PREFERRED EMBODIMENT

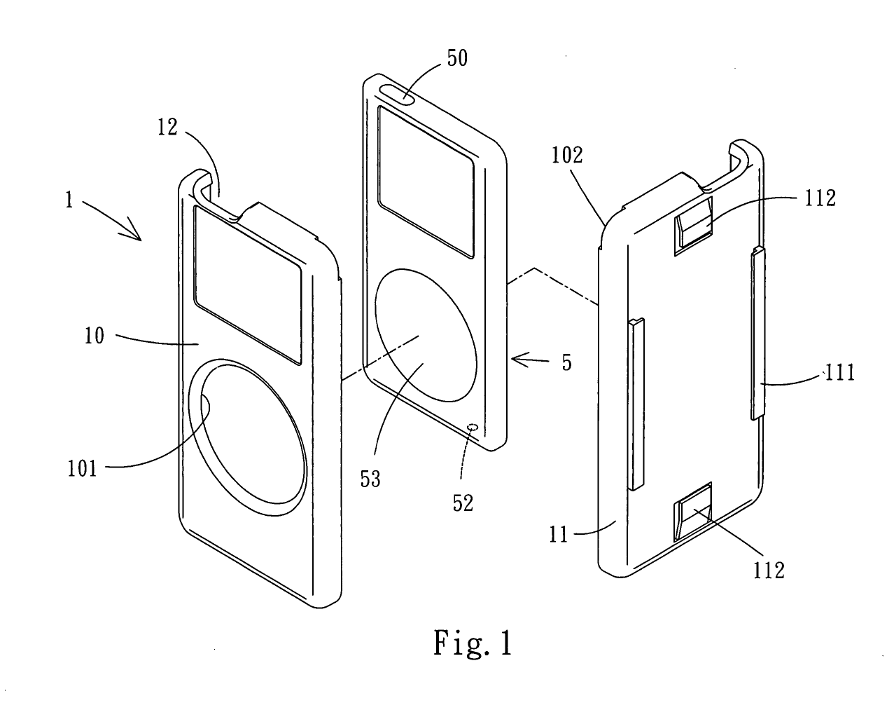

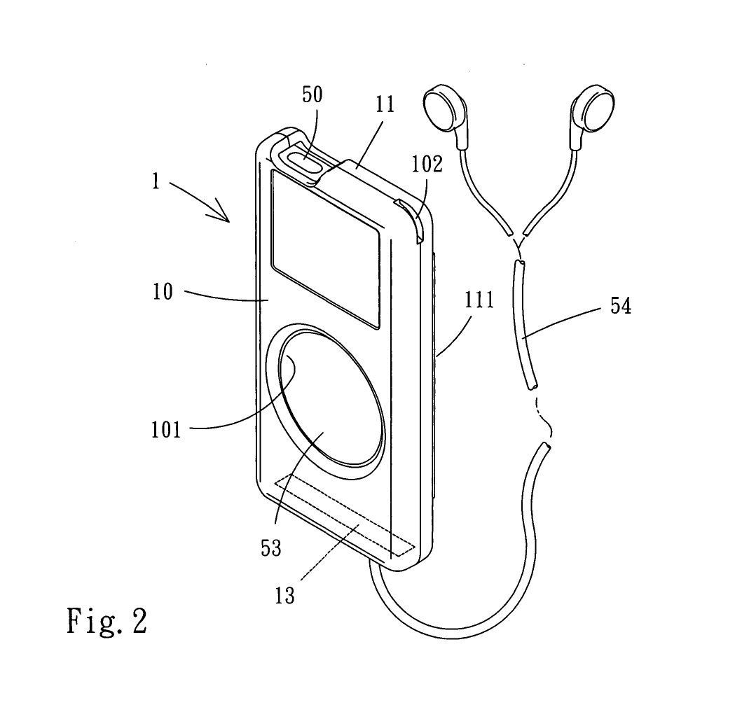

Referring to FIGS. 1 and 2, the protection case 1 for media player of the present invention is composed of a first part 10 and a second part 11. The protection case 1 can be made by Acrylic, PC, ABS, or plastic. Two slots 111 are defined through two sides of the second part 11 and two locking devices 112 located on two ends of the second part 11. A first hole 12 is defined in a top of the protection case 1 and the first hole 12 is located corresponding an ON/OFF switch 50 of the media player 5. A corner slit 102 is defined in a corner of the protection case 1 so that the first and second parts 10, 11 can be separated from each other by inserting a flat object (not shown) and twisting the flat object. A second hole 13 is defined in an underside of the protection case 1 and located corresponding to the ear phone set reception hole of the media player 5 so that the plug (not shown) of the ear phone set 54 can directly connected with the reception hole 52 of the media player 5. Another connection hole such as a USB connection hole 51 is defined in an underside of the media player 5 and can be accessed via the second hole 13 of the protection case 1. A third hole 101 is defined through the first part 11 such that the control disk 53 of the media player 5 as shown in FIG. 1 can be accessed via the third hole 101. By the specific structure of the protection case 1, the user can operate the media player 5 without removing the media player 5 from the protection case 1.

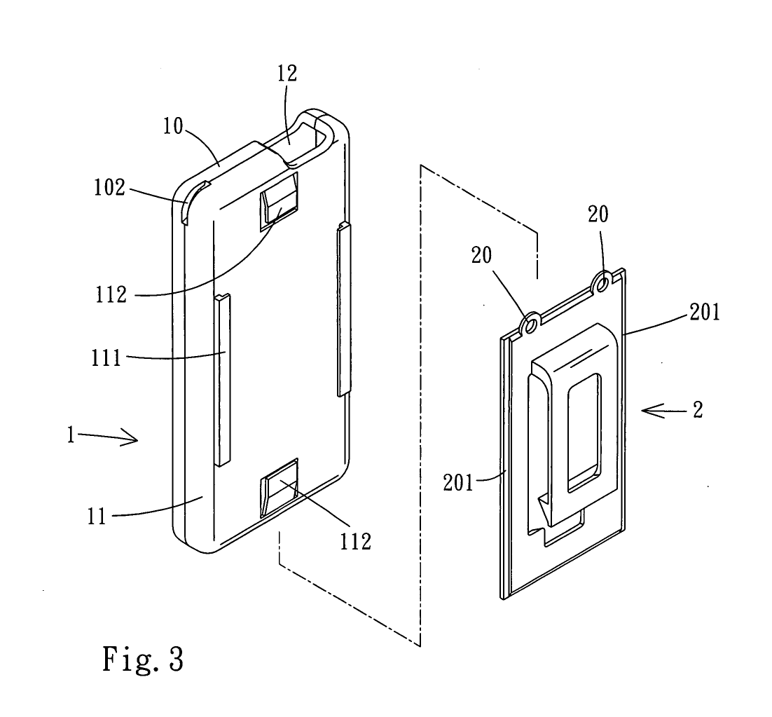

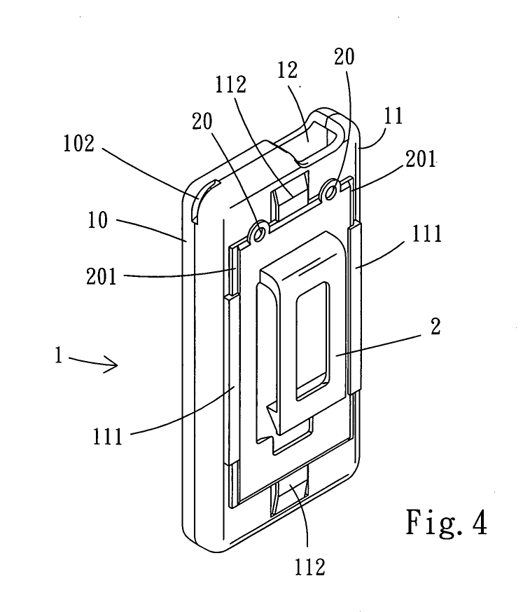

Referring to FIGS. 3, 4, 5A, 6A and 7A, a back board 2 is removably connected to the second part 11 and has two insertions 21 which are inserted into the slots 111 of the second part 11. The back board 2 is attached to the second part 11 by locking the two ends of the back board 2 by the two locking devices 112 on the second part 11. A belt clip is connected to the back board 2 and two holes 20 are defined in an end of the back board 2. The belt clip allows the media player 5 and the protection case 1 to be attached to the user's belt.

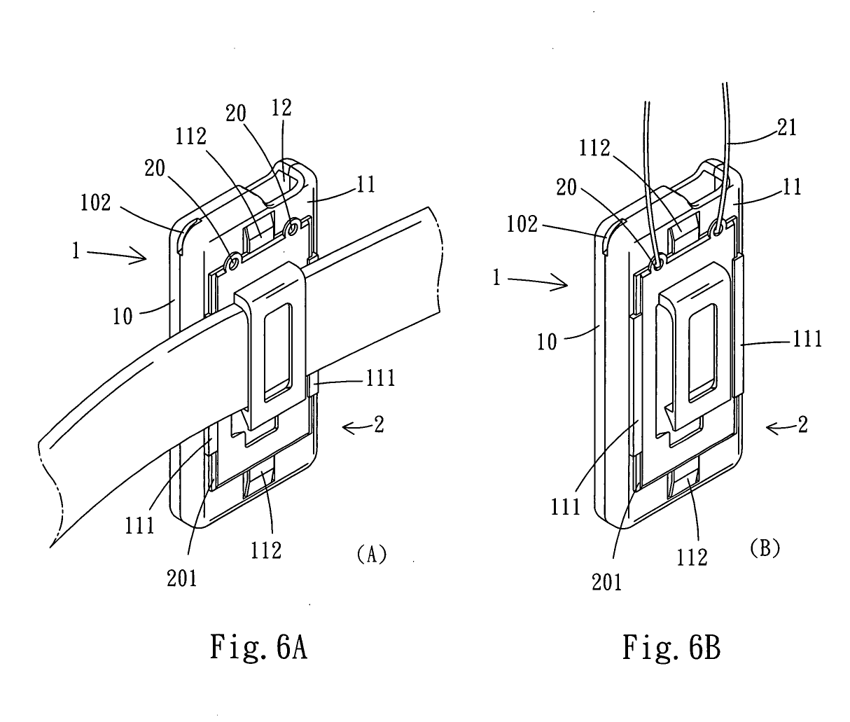

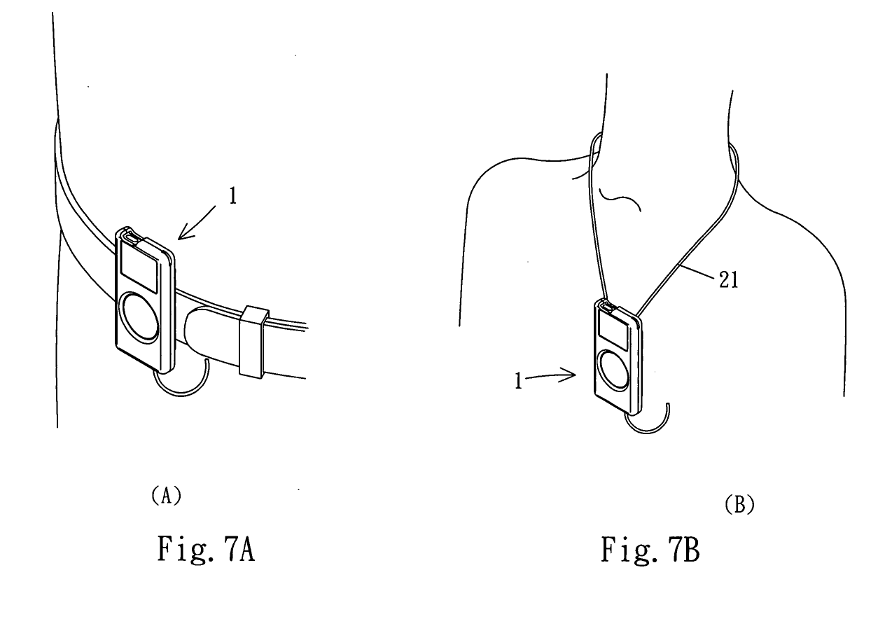

Referring to FIGS. 6B and 7B, a rope 21 extends through the two holes 20 of the back board 2 so as to hang the protection case 1 and the media player 5 on the user's neck.

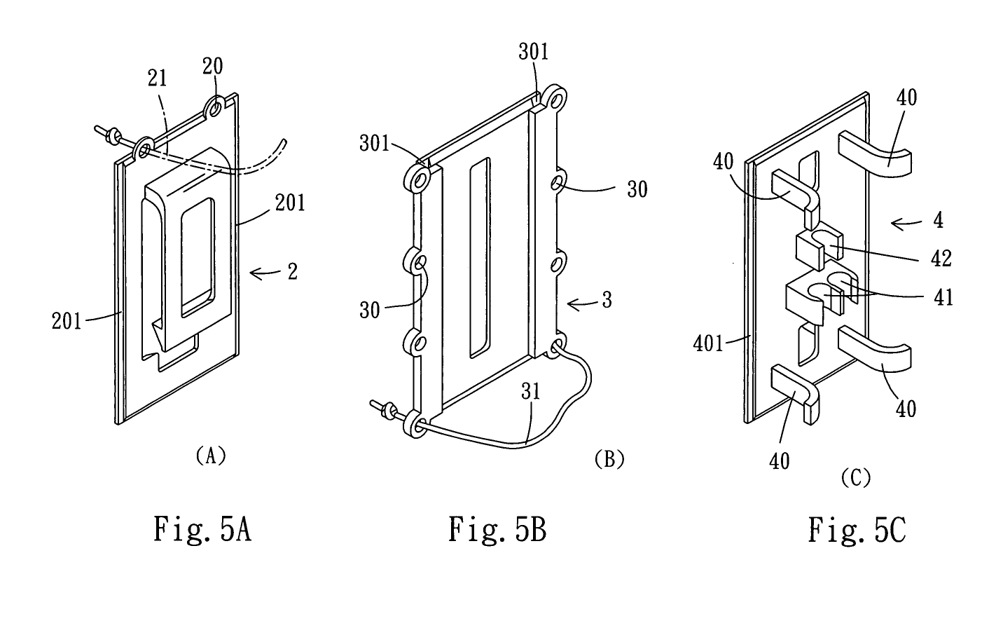

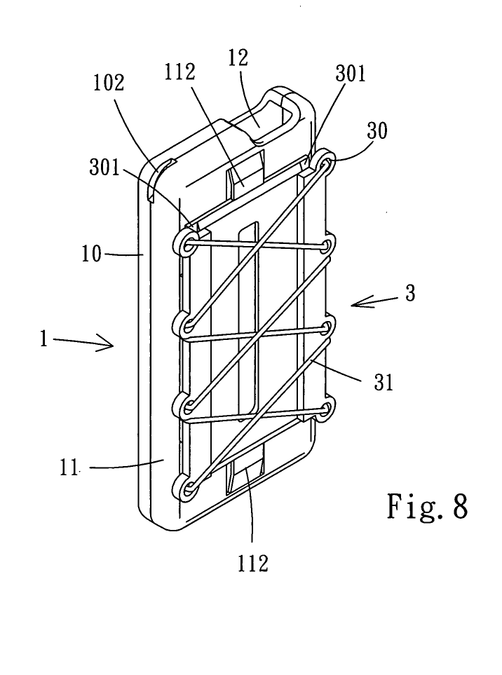

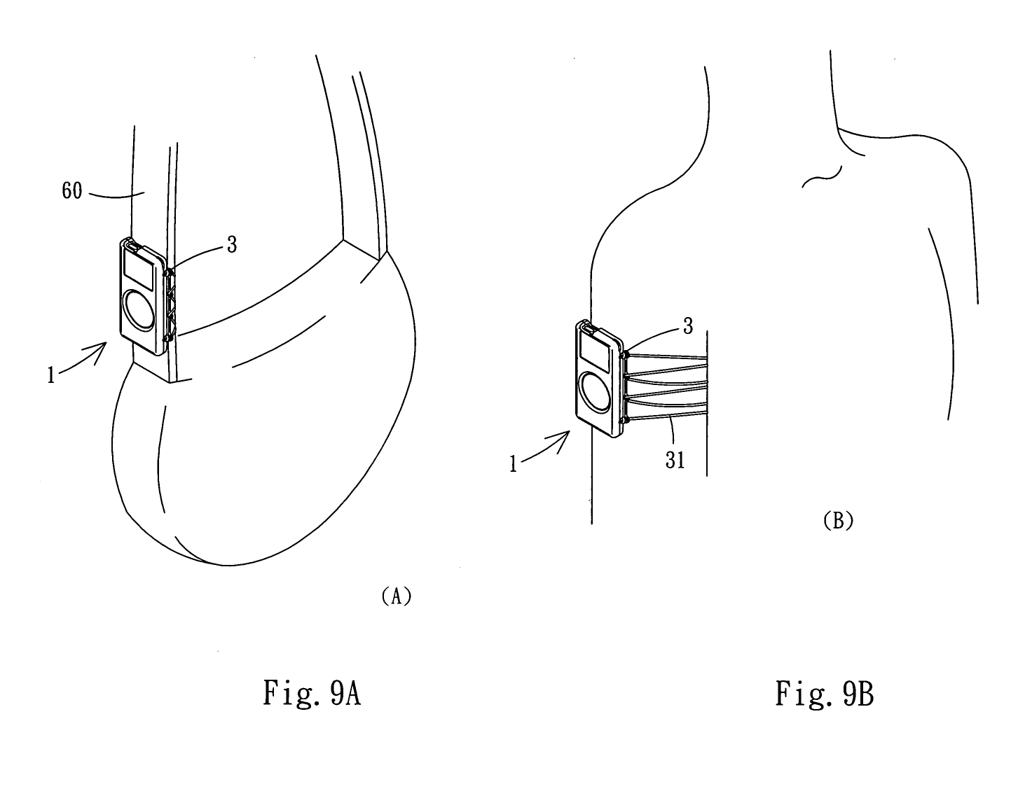

Referring to FIGS. 5B, 8, 9 and 10, the second embodiment of the back board 3 includes a plurality of apertures 30 defined along two sides thereof and a rope 31 alternatively extends through the apertures 30. The rope 31 may be used to tie the protection case 1 and the media player 5 on the strip 60 of a bag, or tie to the user's arm.

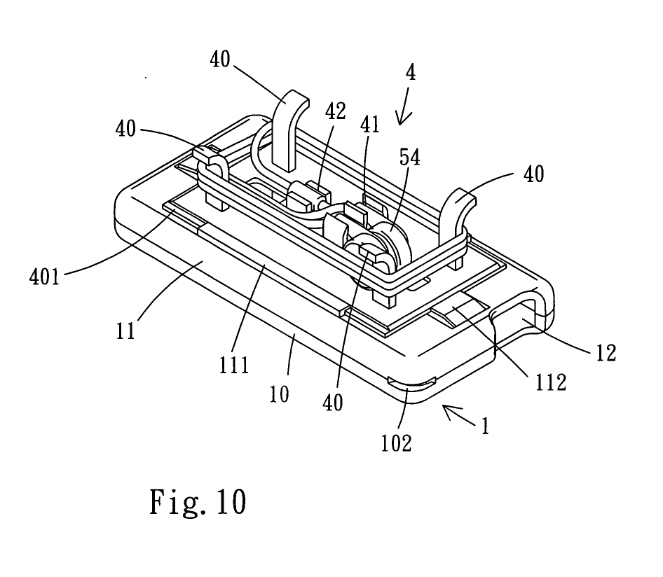

The third embodiment of the back board 4 is shown in FIGS. 5C and 10, wherein the back board 4 includes four protrusions 40 extending therefrom and a dual-recess member 41 and a single-recess member 42 extend from the back board 4. Each of the protrusions 40 includes a bent section which is bent toward two sides of the back board 4 so that the wire of the ear phone set 54 can be wrapped around the four protrusions 40. The bent sections of the protrusions 40 prevent the wire from disengaging from the protrusions 40. The two ear phones are engaged with the two-recess member 41 and the plug of the ear phone set 54 can be engaged with the single-recess member 42.

While we have shown and described the embodiment in accordance with the present invention, it should be clear to those skilled in the art that further embodiments may be made without departing from the scope of the present invention.

What is claimed is:

1. A protection case for media player, comprising:
a first part and a second part, two slots defined through two sides of the second part and two locking devices located on two ends of the second part, and
a back board removably connected to the second part and adapted to be positioned to an object.

2. The protection case as claimed in claim 1, wherein the protection case is made by Acrylic, PC, ABS, or plastic.

3. The protection case as claimed in claim 1, wherein a first hole is defined in a top of the protection case.

4. The protection case as claimed in claim 1, wherein a corner slit is defined in a corner of the protection case.

5. The protection case as claimed in claim 1, wherein a second hole is defined in an underside of the protection case.

6. The protection case as claimed in claim 1, wherein a third hole is defined through the first part.

7. The protection case as claimed in claim 1, wherein the back board has two insertions which are inserted into the slots of the second part, a belt clip is connected to the back board and two holes are defined in an end of the back board.

8. The protection case as claimed in claim 1, wherein the back board includes a plurality of apertures defined along two sides thereof and a rope alternatively extends through the apertures.

9. The protection case as claimed in claim 1, wherein the back board includes a plurality of protrusions extending therefrom and a dual-recess member and a single-recess member extend from the back board.

10. The protection case as claimed in claim 9, wherein each of the protrusions includes a bent section which is bent toward two sides of the back board.
